(19) United States
(12) Patent Application Publication
(10) Pub. No.: US 2011/0315984 A1
(43) Pub. Date: Dec. 29, 2011

(54) SEMICONDUCTOR MEMORY CARD AND METHOD OF MANUFACTURING THE SAME

(75) Inventors: Hidetoshi SUZUKI, Kanagawa (JP); Toshiyuki Hayakawa, Kanagawa (JP); Yuka Nagashima, Kanagawa (JP)

(73) Assignee: Kabushiki Kaisha Toshiba, Tokyo (JP)

(21) Appl. No.: 13/052,164

(22) Filed: Mar. 21, 2011

(30) Foreign Application Priority Data
Jun. 25, 2010 (JP) 2010-144375

(51) Int. Cl. H01L 23/488; H01L 21/56; H01L 21/58

(52) U.S. Cl. 257/48; 438/126; 257/E23.023; 257/E21.505; 257/E21.502

(57) ABSTRACT

According to one embodiment, a semiconductor memory card that includes a printed substrate in which an electronic component is mounted on one surface, and an external terminal is installed on the other surface, and that is molded in a card form. The printed substrate is a laminated body in which a metallic interconnection for connecting the electronic component to the terminal and a solder resist are sequentially laminated on both surfaces of a core material. The semiconductor memory card includes an ink layer on the solder resist of the other surface, and a mark is engraved by a laser on the ink layer.

### CROSS-REFERENCE TO RELATED APPLICATIONS

This application is based upon and claims the benefit of priority from the prior Japanese Patent Application No. 2010-144375, filed on Jun. 25, 2010; the entire contents of which are incorporated herein by reference.

### FIELD

Embodiments described herein relate generally to a semiconductor memory card and a method of manufacturing the same.

### BACKGROUND

There has been used a semiconductor memory card in which a non-volatile semiconductor memory (for example, an NAND type flash memory) and a controller are mounted on one surface of a printed substrate, an electrode pad for reading and writing data is installed on the other surface, the semiconductor memory, the controller, and the electrode pad are connected by a copper (Cu) interconnection, and the copper interconnection is protected and hidden by covering both surfaces with a solder resist.

For marking on such a semiconductor memory card, a technique such as printing using ink or marking using a laser has been used. Particularly, for displaying information of the printing content that frequently changes, such as a weekly code (a number representing which week of the year the product is manufactured) or a lot number, marking by a laser has generally been used because it is easy to cope with the change of information.

For example, in the case of a micro SD™ memory card (hereinafter, micro SD memory card), a logo of SD or a manufacturing country name is printed on a resin surface of a card (a surface on which the semiconductor memory or the controller is mounted) by ink, and the weekly code is marked using a laser.

In engraving the mark on the semiconductor memory card by a laser, it is necessary to avoid a problem of damaging the function of a semiconductor memory card while engraving the mark.

### BRIEF DESCRIPTION OF THE DRAWINGS

FIG. 1 is a plane diagram of a micro SD memory card as a semiconductor memory card according to a first embodiment;

FIG. 2 is a cross-sectional diagram of the micro SD memory card according to the first embodiment;

FIG. 3 is a diagram illustrating an example of a configuration of a printed substrate applied to a micro SD memory card;

FIG. 4 is a diagram illustrating an example of a micro SD memory card in which an image related to a content previously recorded in a semiconductor memory is printed as a design layer;

FIG. 5 is a diagram illustrating an example of a state in which a mark is engraved on a terminal surface of a micro SD memory card using a laser oscillator;

FIG. 6 is a cross-sectional diagram of a micro SD memory card of a reference example realized by the inventor;

FIG. 7 is a cross-sectional diagram illustrating a configuration of a micro SD memory card in which a mark does not reach a Cu interconnection by increasing the film thickness of a solder resist of a terminal surface;

FIG. 8 is a diagram illustrating a state in which a non-cured solder resist drapes over an electrode terminal or a test terminal;

FIG. 9 is a cross-sectional diagram of a micro SD memory card as a semiconductor memory card according to a second embodiment;

FIG. 10 is a plane diagram of a micro SD memory card as a semiconductor memory card according to a third embodiment;

FIG. 11 is a cross-sectional diagram of the micro SD memory card according to the third embodiment;

FIG. 12 is a diagram illustrating an example of a state in which a mark is engraved on a terminal surface of a micro SD memory card using a laser oscillator;

FIG. 13A is a plane diagram of a micro SD memory card in which a floating interconnection is formed on a resin surface of a printing area and

FIG. 13B is a cross-sectional diagram of a micro SD memory card in which a floating interconnection is formed on a resin surface of a printing area.

### DETAILED DESCRIPTION

In general, according to one embodiment, a semiconductor memory card that includes a printed substrate in which an electronic component including a semiconductor memory is mounted on one surface, and an external terminal for inputting/outputting data to/from the semiconductor memory is installed on the other surface, and that is molded in a card form in which one surface of the printed substrate is sealed by resin. The printed substrate is a laminated body in which a metallic interconnection connecting the electronic component to the external terminal and a solder resist covering a surface of a core material and the metallic interconnection are sequentially laminated on both surfaces of the core material as a base material. An ink layer is formed on the solder resist inside of a predetermined area of a surface of the printed substrate on which the external terminal is installed. An mark is engraved by a laser on the ink layer.

Exemplary embodiments of semiconductor memory card and method of manufacturing the same will be explained below in detail with reference to the accompanying drawings. The present invention is not limited to the following embodiments.

In each of the following embodiments, a micro SD memory card will be described as an example of a semiconductor memory card according to one of the following embodiments, but the present invention is not limited thereto. For example, a semiconductor memory card that conforms to any other standard may be used.

### First Embodiment

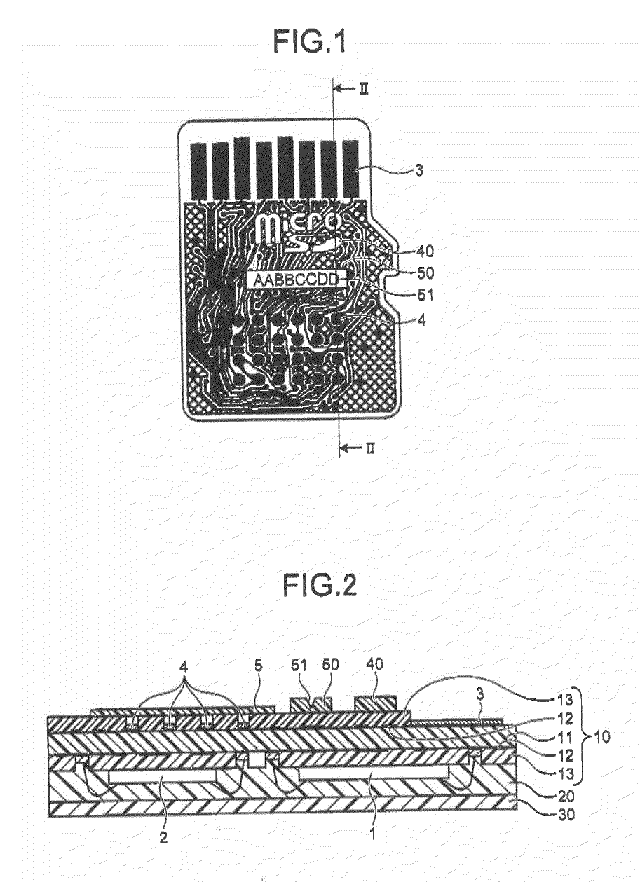

FIG. 1 is a plane diagram of a micro SD memory card as a semiconductor memory card according to a first embodiment. FIG. 2 is a cross-sectional diagram of the micro SD memory card according to the first embodiment. FIG. 2 illustrates a cross section taken along line II-II of FIG. 1. A semiconductor memory 1 and a controller 2 for writing/reading data to/from the semiconductor memory 1 are mounted on one surface of a printed substrate 10. An electrode terminal 3 as an external terminal for reading and writing data and a test terminal 4 for solely testing the semiconductor memory 1 are disposed on the other surface of the printed substrate 10. The whole surface of the printed substrate 10 on which electronic components such as the semiconductor memory 1 and the controller 2 are mounted are sealed by a resin mold 20. The number of semiconductor memories 1 mounted on the printed substrate 10 is arbitrary, but by mounting one semiconductor memory 1 and one controller 2, a structure or an assembly work of the micro SD memory card can be simplified, and the manufacturing cost can be reduced.

In the following description, of the two surfaces of the micro SD memory card, the surface on which the semiconductor memory 1 and the controller 2 are mounted is referred to as a resin surface, and the surface on which the electrode terminal 3 and the test terminal 4 are installed is referred to as a terminal surface.

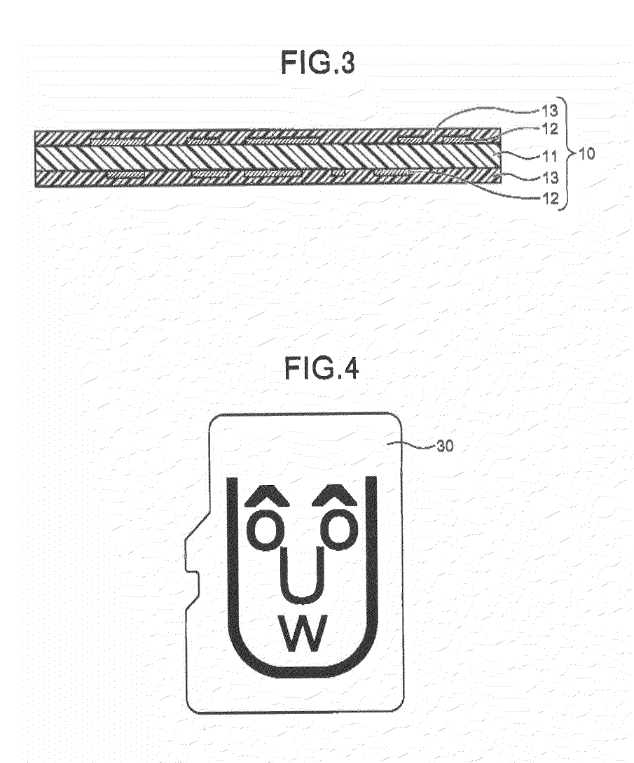

FIG. 3 is a diagram illustrating an example of a configuration of the printed substrate 10 applied to the micro SD memory card according to this embodiment. A core material 11 is, for example, a glass epoxy substrate. Copper (Cu) interconnection layers for forming Cu interconnections 12 as a metallic interconnection are formed on both surfaces of the core material 11, and electronic components such as the semiconductor memory 1 and the controller 2 are electrically connected with the electrode terminal 3 and the test terminal 4 through the Cu interconnection 12. Except for the portions in which a mounting pad of the semiconductor memory 1 or the controller 2, the electrode terminal 3, and the test terminal 4 are installed, almost the whole surface is covered with a solder resist 13 from the top of the Cu interconnection layer. The solder resist 13 is formed on an area excluding the portions in which the electrode terminal 3, the mounting pad, and the test terminal 4 are installed by masking the portions in which the electrode terminal 3, the mounting pad, and the test terminal 4 are installed, then coating thermally-cured or ultraviolet-cured resist ink or laminating a sheet-like molding on a core material, and thereafter removing unnecessary portions. As the resist ink, there may be used a typical one that contains thermally-cured epoxy-based resin, ultraviolet-cured epoxy-based resin, or ultraviolet-cured acrylate-based resin as a component.

As an example of a dimension of each layer that constitutes the printed substrate 10, the thickness of the core material 11 is about 100 μm, the thickness of the Cu interconnection 12 is about 12 μm to 25 μm, the thickness from the surface of the core material 11 to the surface of the solder resist 13 is about 50 μm, and the thickness of the solder resist 13 above the Cu interconnection 12 is about 25 μm to 38 μm. The values are only examples, and the present invention is not limited thereto.

The test terminal 4 is hidden by a mask label 5 (not shown in FIG. 1) and is not exposed in a normal state. In order to analyze the cause of a failure occurring in the micro SD memory card, the mask label 5 is peeled off to expose the test terminal 4, and a solely test of the semiconductor memory 1 is performed. In the case in which the controller 2 has a function of testing the semiconductor memory 1 so that it is unnecessary to perform the solely test of the semiconductor memory 1 at the time of manufacturing, the solder resist 13 may also be formed on the test terminal 4, and thus the solder resist 13 may be removed to perform the solely test of the semiconductor memory 1 at the time of analyzing the cause of failure.

On the resin surface of the card, a design layer 30 for displaying information desired by a content maker is formed. For example, on the resin surface of the micro SD memory card in which a predetermined content is recorded in the semiconductor memory 1, the design layer 30 may be formed by printing information related to the content. Specifically, in the case of the micro SD memory card in which data such as a still image or a moving image of a certain animation character is recorded in the semiconductor memory 1, the design layer 30 may be formed by printing an image of the character. Information displayed on the resin surface by the design layer 30 is not limited to an image but may include a character string. The design layer 30 is not limited to a printed layer and may be attached to the resin surface as a seal. Further, a content maker may perform identification marking on the design layer 30 through an arbitrary method (for example, marking by a laser).

Examples of the contents recorded in the semiconductor memory 1 include a mobile terminal application, a standby image, a ringtone, and an animation of a mobile phone unit. By inserting the micro SD memory card according to this embodiment into a mobile terminal including a micro SD memory card connector, the contents previously recorded in the semiconductor memory 1 can be used by the mobile terminal. As a method of installing the contents, for example, in the mobile terminal, a download method using a communication function of the mobile terminal may be considered. However, in this method, since the mobile terminal has to exist under an environment in which communication can be performed for download, the communication cost occurs. Thus, by installing the content using the micro SD memory card in which the contents are previously recorded, the limitation of place or the occurrence of the communication cost can be avoided.

As a business model using the micro SD card in which the contents are previously recorded, it may be considered that the content maker sells the micro SD memory card to a user of the mobile terminal (an end user). In this case, even if the content previously recorded in the semiconductor memory 1 is the same, by changing the content of information printed on the resin surface as the design layer 30, the value as a commercial product can change. For example, by making some micro SD memory cards in which the same content is previously recorded in the semiconductor memory 1 as a card having a high rarity value (a rare card) in which an image printed on the resin surface as the design layer 30 is changed, the end user's willingness to buy can be encouraged.

FIG. 4 is a diagram illustrating an example of a micro SD memory card in which an image related to the content previously recorded in the semiconductor memory 1 is printed as the design layer 30. As illustrated in FIG. 4, since the design layer 30 is formed on the resin surface, information such as a logo mark or a lot number of the micro SD memory card cannot be printed or marked on the resin surface. Since a logo of the micro SD is required to be displayed by the standard, hiding it is not allowed. It is not a requirement to display information such as the lot number or the capacity of the semiconductor memory 1 by the standard, but it is necessary to display it so that a card manufacturer may manage the product. For this reason, in this embodiment, information that has a low frequency of being changed, such as a logo mark or a manufacturing country name, is printed on the terminal surface. A logo of SD or a manufacturing country name is printed on the terminal surface as a printing layer 40 by a technique such as pad printing or silk printing.

An ink layer 50 is formed on a predetermined area (a printing area) of the terminal surface. Forming the ink layer 50 may be performed by the same process as printing of the printing layer 40. Further, a different process may be performed.

A mark 51 is performed on the ink layer 50 by a laser, and information that has a high frequency of being changed, such as the lot number or the capacity of the semiconductor memory 1, is displayed by the mark 51. The mark 51 does not penetrate the ink layer 50, and thus the solder resist 13 remains undamaged. Accordingly, the Cu interconnection 12 below the mark 51 is protected by the solder resist 13 equally to a spot in which the mark 51 is not performed.

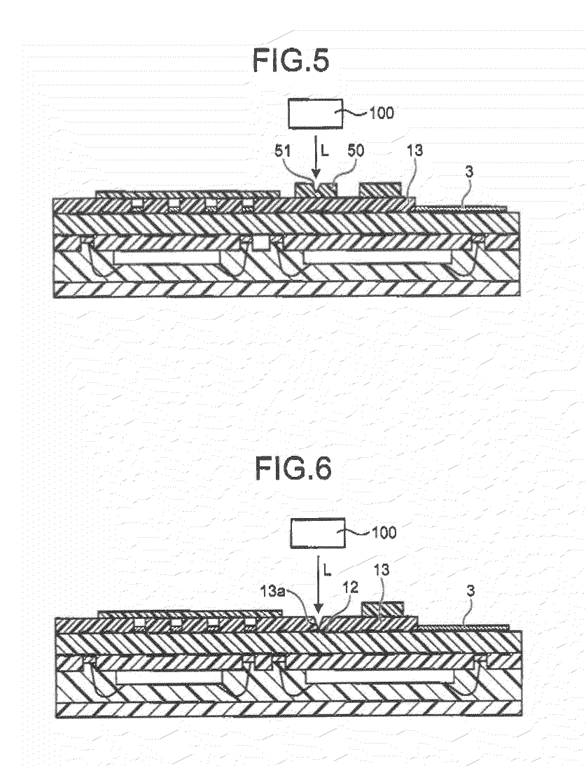

FIG. 5 is a diagram illustrating an example of a state in which a mark is engraved on the terminal surface of the micro SD memory card using a laser oscillator 100. A laser L emitted from the laser oscillator 100 is irradiated onto the ink layer 50. The laser L is attenuated in the ink layer 50 and forms the mark 51 at the depth in which the ink layer 50 is not penetrated. As an example, in the case of oscillating the laser oscillator 100 at 40 A as a maximum value of an output current, the depth of the mark 51 is about 15 μm at average and about 22 μm at maximum. In this case, if the ink layer 50 is thicker than 22 μm, the mark 51 does not reach the solder resist 13. That is, even if the mark 51 is formed, the Cu interconnection 12 formed on the surface of the core material 11 is not exposed. For this reason, in the micro SD memory card according to this embodiment, a problem such as an electrical short circuit or corrosion of the Cu interconnection 12 does not occur.

For comparison, a micro SD memory card of a reference example realized by the inventor will be described. FIG. 6 is a cross-sectional diagram of a micro SD memory card of a reference example realized by the inventor. The micro SD memory card of the reference example is different from the micro SD memory card according to this embodiment in that the ink layer 50 is not formed. The laser L that has been emitted from the laser oscillator 100 and irradiated directly onto the solder resist 13 penetrates the solder resist 13 and reaches the Cu interconnection 12. That is, the Cu interconnection 12 is exposed in a portion in which mark 13a is engraved by the laser L. If the Cu interconnection 12 is exposed, an electrical short circuit may occur through the exposed portion. Further, corrosion of the Cu interconnection 12 may occur in the exposed portion. Since the solder resist 13 on the Cu interconnection 12 of the printed substrate 10 has the thickness of about 25 μm to 38 μm, if the maximum value of the output current of the laser oscillator 100 is 40 A, the mark 13a does not penetrate the solder resist 13. However, if the maximum value of the output current increases, the mark 13a penetrates the solder resist 13, and thus the Cu interconnection 12 may be exposed.

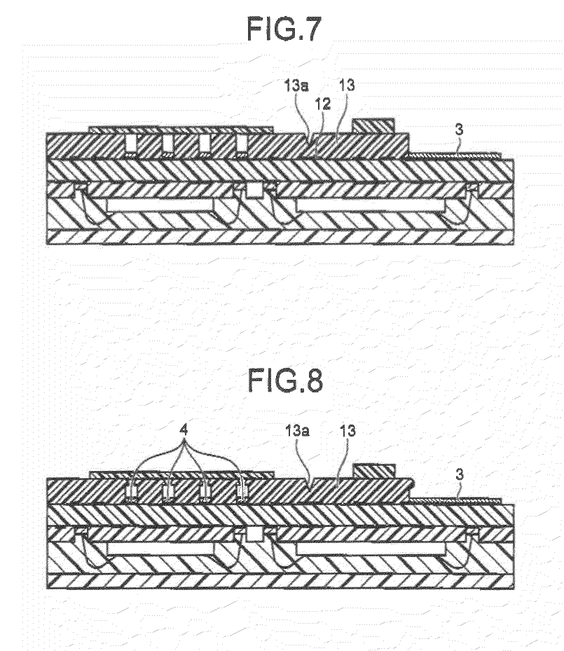

Further, for comparison, a micro SD memory card in which the film thickness of the solder resist of the terminal surface is increased will be described. FIG. 7 is a cross-sectional diagram illustrating a configuration of a micro SD memory card in which the mark 13a does not reach the Cu interconnection 12 by increasing the film thickness of the solder resist of the terminal surface. The micro SD memory card of FIG. 7 is similar to the micro SD memory card illustrated in FIG. 2 except the film thickness of the solder resist 13 of the terminal surface.

A shape dimension of the micro SD memory card is decided by the standard, and a card insert hole of a connector for reading/writing data from/to the micro SD memory card also has the size conforming to the standard. Thus, if the film thickness of the solder resist 13 simply increases, the clearance with the card insert hole decreases, and thus it is difficult to insert/remove it into/from a connector.

In order to expose the electrode terminal 3, it is necessary to remove the solder resist 13 from an area directly above the electrode terminal 3. For this reason, if the film thickness of the solder resist 13 simply increases, a difference in height (a step difference) between the solder resist 13 and the electrode terminal 3 in an edge part of the electrode terminal 3 increases, and thus it is difficult to make a connection with a terminal of the connector. In the case of forming the solder resist by coating and curing thermally-cured resin or ultraviolet-cured resin, if an attempt to increase the film thickness of the solder resist is made, as illustrated in FIG. 8, the solder resist 13 that is not cured may drape over the electrode terminal 3 or the test terminal 4. If the resin drapes over the electrode terminal 3 or the test terminal 4, a conduction failure is caused.

As described above, in the micro SD memory card in which the film thickness of the solder resist 13 is simply increased in order to prevent the mark 13a from reaching the Cu interconnection 12, there may be a problem in that it is difficult to insert/remove it into/from the connector or a conduction failure of the electrode terminal 3 or the test terminal 4 occurs.

As described above, in the micro SD memory card according to this embodiment, a mark by a laser is engraved on the terminal surface, but the mark does not penetrate the ink layer and remains in the ink layer. Thus, an electrical failure caused by exposure of the Cu interconnection does not occur.

### Second Embodiment

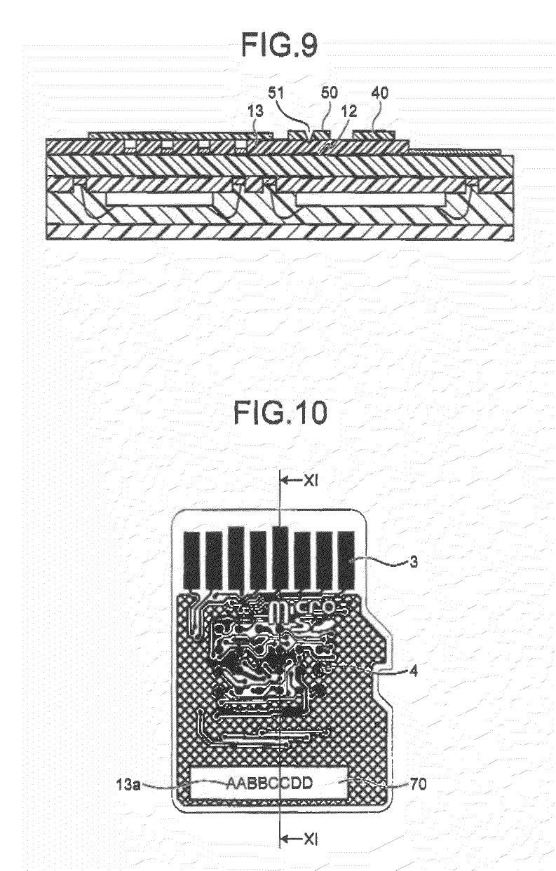

FIG. 9 is a cross-sectional diagram of a micro SD memory card as a semiconductor memory card according to a second embodiment. A configuration of the micro SD memory card is almost the same as in the first embodiment, but in this embodiment, the ink layer 50 is formed thinner than in the first embodiment.

In this embodiment, the mark 51 by the laser does not remain in the ink layer 50 but reaches the solder resist 13. However, the mark 51 does not reach the Cu interconnection 12. For this reason, similarly to the first embodiment, an electrical failure caused by exposure of the Cu interconnection 12 does not occur.

If the mark 51 is shallow, visibility deteriorates. Thus, in the case of forming the ink layer 50 by the same process as the printing layer 40, it may be difficult to form the ink layer 50 at the thickness in which the mark 51 of the depth having sufficient visibility remains in the ink layer 50. In this case, even though the mark 51 reaches the solder resist 13, if the ink layer 50 is formed at the film thickness enough to prevent the solder resist 3 from being penetrated, exposure of the Cu interconnection 12 can be prevented.

The other configuration is similar to the first embodiment, and the description thereof will not be repeated.

### Third Embodiment

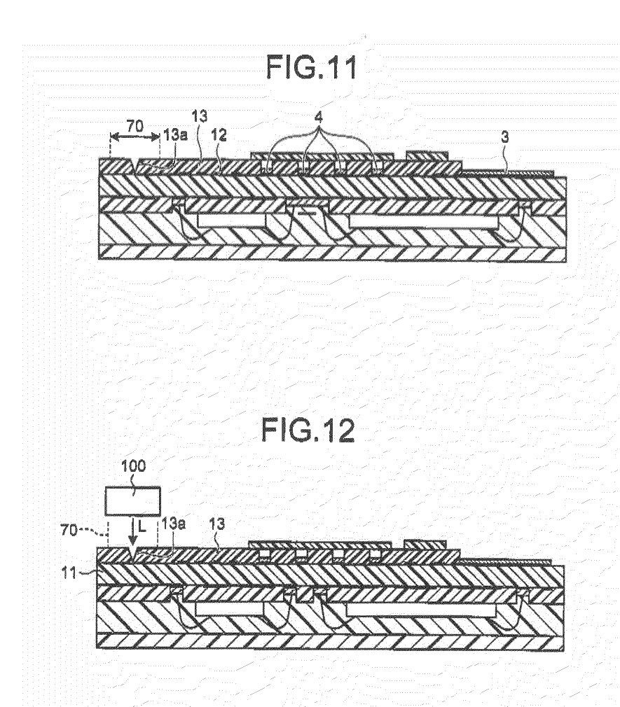

FIG. 10 is a plane diagram of a micro SD memory card as a semiconductor memory card according to a third embodiment. FIG. 11 is a cross-sectional diagram of the micro SD memory card according to the third embodiment. FIG. 11 illustrates a cross section taken along line XI-XI of FIG. 10. A structure of the micro SD memory card is almost the same as in the first and second embodiment, but in this embodiment, the ink layer is not formed. Compared to the micro SD memory card according to the first embodiment, the test terminals 4 are concentrated at the position close to the electrode terminal 3, and an area (a printing area 70) in which the Cu interconnection 12 does not exist is disposed on the terminal surface at the position near an end portion of a side opposite to the electrode terminal 3. The mark 13a is formed in the solder resist 13 inside of the printing area 70.

FIG. 12 is a diagram illustrating an example of a state in which a mark is engraved on the terminal surface of the micro SD memory card using the laser oscillator 100. A laser L emitted from the laser oscillator 100 is irradiated onto the solder resistor 13. Since the Cu interconnection 12 is not formed on the terminal surface of the printing area 70, even if the mark 13a by the laser L reaches the core material 11, the Cu interconnection 12 is not exposed in the mark portion.

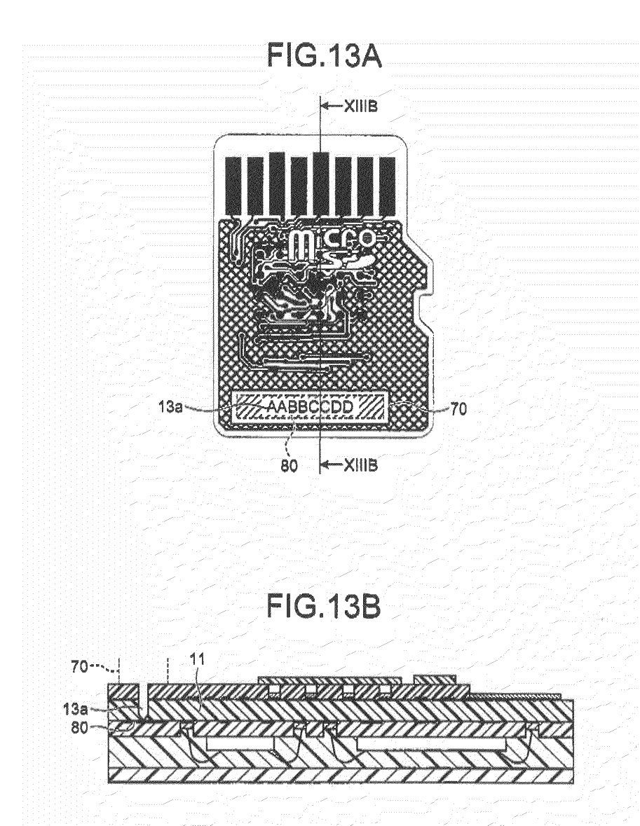

Further, there is a possibility that the mark 13a will penetrate the core material 11 as well as the solder resist 13 of the terminal surface depending on an output of the laser. In this case, if the Cu interconnection 12 or the mounting pad of the electronic component exists on the resin surface of the printing area 70 or the semiconductor memory is mounted on the resin surface of the printing area 70, they may be damaged by the laser. In order to avoid such a failure, as illustrated in FIG. 13A and FIG. 13B, it is preferable to form a Cu interconnection (a floating interconnection 80) of a floating state on the resin surface of the printing area 70. FIG. 13B illustrates a cross section taken along line XIIIB-XIIIB of FIG. 13A. The mark 13a that has penetrated the solder resist 13 and the core material 11 at the terminal surface and reaches the resin surface is stopped by the floating interconnection 80. Since the floating interconnection 80 is not involved in an operation of the micro SD memory card, it does not cause the occurrence of an electric short circuit. Further, even if it contacts the air and is corroded, it does not disrupt an operation of the micro SD memory card.

The floating interconnection BO may be formed at the terminal surface, but when the floating interconnection BO is formed at the resin surface, even if it is exposed, it is not recognized, and thus it does not causes disfigurement of the micro SD memory card.

The other configuration is similar to the first and second embodiments, and thus the description thereof will not be repeated.

As described above, in the printed substrate applied to the micro SD memory card according to this embodiment, the Cu interconnection is formed at an area other than the printing area. Thus, even when mark is engraved by the laser, a problem such as an electrical short circuit or corrosion of the Cu interconnection does not occur.

The several embodiments have been described above, but the embodiments may be combined and implemented. For example, the semiconductor memory card may have both the printing layer and the printing area, and a mark may be engraved on each of the printing layer and the printing area by the laser. Further, it may be possible to realize an embodiment in which the printing area having the floating interconnection and the printing layer are combined.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory card that includes a printed substrate in which an electronic component including a semiconductor memory is mounted on one surface, and an external terminal for inputting/outputting data to/from the semiconductor memory is installed on the other surface, and that is molded in a card form in which one surface of the printed substrate is sealed by resin,
wherein the printed substrate is a laminated body in which a metallic interconnection connecting the electronic component to the external terminal and a solder resist covering a surface of a core material and the metallic interconnection are sequentially laminated on both surfaces of the core material as a base material,
an ink layer is formed on the solder resist inside of a predetermined area of a surface of the printed substrate on which the external terminal is installed, and
a mark is engraved by a laser on the ink layer.

2. The semiconductor memory card according to claim 1,
wherein the mark does not reach the metallic interconnection hidden by the solder resist below the ink layer.

3. The semiconductor memory card according to claim 2,
wherein the mark does not reach the solder resist below the ink layer.

4. The semiconductor memory card according to claim 2,
wherein the mark penetrates the ink layer and reaches the solder resist.

5. The semiconductor memory card according to claim 2,
wherein information related to data previously recorded in the semiconductor memory is displayed above the surface sealed by the resin.

6. The semiconductor memory card according to claim 2,
wherein the printed substrate comprises a test terminal for testing the electronic component above the core material of the other surface.

7. The semiconductor memory card according to claim 6,
wherein a mask label is attached to the other surface of the printed substrate to hide the test terminal.

8. The semiconductor memory card according to claim 6,
wherein the test terminal is covered with the solder resist.

9. The semiconductor memory card according to claim 2,
wherein a printing area in which the metallic interconnection is not arranged is formed in a predetermined area of a surface in which the external terminal is installed, and
a mark is engraved by a laser on the solder resist inside of the printing area.

10. The semiconductor memory card according to claim 9,
wherein a floating interconnection that is electrically isolated is formed on any one surface of the core material inside of the printing area.

11. A semiconductor memory card that includes a printed substrate in which an electronic component including a semiconductor memory is mounted on one surface, and an external terminal for an input/output of data to/from the semiconductor memory is installed on the other surface, and that is molded in a card form in which one surface of the printed substrate is sealed by resin,
wherein the printed substrate is a laminated body in which a metallic interconnection connecting the electronic component to the external terminal and a solder resist covering a surface of a core material and the metallic interconnection are sequentially laminated on both surfaces of the core material as a base material,
a printing area in which the metallic interconnection is not arranged is formed in a predetermined area of a surface in which the external terminal is installed, and
a mark is engraved by a laser on the solder resist inside of the printing area.

12. The semiconductor memory card according to claim 11,
wherein a floating interconnection that is electrically isolated is formed on any one surface of the core material inside of the printing area.

13. The semiconductor memory card according to claim 11,
wherein information related to data previously recorded in the semiconductor memory is displayed above the surface sealed by the resin.

14. The semiconductor memory card according to claim 11,
wherein the printed substrate comprises a test terminal for testing the electronic component above the core material of the other surface.

15. The semiconductor memory card according to claim 14,
wherein a mask label is attached to the other surface of the printed substrate to hide the test terminal.

16. The semiconductor memory card according to claim 14,
wherein the test terminal is covered with the solder resist.

17. A method of manufacturing a semiconductor memory card, comprising:
mounting an electronic component on the other surface of a printed substrate that is formed as a laminated body in which a metallic interconnection connecting the electronic component to the external terminal and a solder resist covering a surface of a core material and the metallic interconnection are sequentially laminated on both surfaces of the core material as a base material, and an external terminal for inputting/outputting data to/from the semiconductor memory is installed on one surface;
molding in a card form by sealing the other surface of the printed substrate by resin;
forming an ink layer on the solder resist inside of a predetermined area of one surface of the printed substrate; and
engraving a mark by a laser in the ink layer not to reach the metallic interconnection hidden by the solder resist below the ink layer, so that information is displayed on the ink layer by the mark.
